(19) United States
(12) Patent Application Publication
(10) Pub. No.: US 2017/0265302 A1
(43) Pub. Date: Sep. 14, 2017

(54) MULTI-DIRECTION INSTALLATION PRACTICABLE LED LIGHTING POWER SOURCE LAMP BASE

(71) Applicant: GUM SOON KIM, Incheon (KR)

(72) Inventor: GUM SOON KIM, Incheon (KR)

(21) Appl. No.: 15/063,635

(22) Filed: Mar. 8, 2016

(51) Int. Cl. H05K 1/18; F21V 15/01

(52) U.S. Cl. CPC H05K 1/181; F21V 15/01; H05K 2201/10106; F21Y 2101/02

(57) ABSTRACT

This invention includes a base having open sides and an open bottom, a housing keeping a printed circuit board having an LED module thereon, and connected to a side of the base, and a base cover coupled to the lower portion of the base to fix the connection of the side of the base and the housing. According to this invention, it is possible to install a lamp including an LED module even without a specific skill in accordance with desired indoor illumination requirement, thus there is no need for unnecessary work for installing a housing for the LED lamp. Therefore, it is possible to remarkably reduce the cost for to installation and to install an LED lamp in accordance with desired indoor illumination requirements. Further, there is no need for installing a base on a ceiling, so an interior effect can be maximized and sufficient indoor illumination can be ensured.

### BACKGROUND OF THE INVENTION

Field of the Invention

The present invention relates to a power source lamp base for supplying power to a lamp composed of LEDs and, more particularly, to a multi-direction installation practicable LED lighting power source lamp base that provides convenience, in use, is to efficiently combined with a lamp, and provides efficiency in work by coupling an end of an LED lamp housing in MO directions, four directions, or six directions using one base.

Description of the Related Art

In general, in order to supply power to a lamp fixed to a ceiling including a lighting is element such as an LED, there is a need for a housing that is long and keeps a printed circuit board with an LED thereon and a fixing plate and a fixing bracket for fixing the lamp at a middle portion. An inverter is disposed on the fixing plate or sockets are formed at both ends of the housing to replace a fluorescent lamp to connect a terminal such as a fluorescent lamp.

LEDs have replaced a fluorescent lamp and various technologies have been developed, so a housing for fitting a fluorescent lamp is little used and efforts and studies for replacing an incandescent light and a fluorescent lamp, for example, by improving the housing to fit to LEDs have been made.

A lamp using an LED having a common structure includes a housing, a fixing plate in which an inverter is inserted at the center, a translucent acryl cover disposed at the upper portion, that is, over the housing to transmit light from as LED to light the interior, and a center cover for covering the center.

Common LED lamps generally have a straight shape, so a plurality of straight LEDs is disposed at predetermined intervals to meet desired indoor illumination requirements.

Considering indoor illumination and lighting efficiency, it is required to set the number of LED lamps to be installed on the ceiling, for example, it is required to install more LED lamps to the ceiling or ceiling hoards for an interior that requires high illumination.

### PRIOR ART DOCUMENT

### Patent Document

(Patent Document 1) Korean Patent Application Publication No. 10-2011-0088709 (publicated on Aug. 4, 2011)

### SUMMARY OF THE INVENTION

An object of the present invention is to minimize installation cost and maximize work efficiency and illumination efficiency by removing unnecessary work for installing an LED lamp housing by installing an LED lamp to meet desired indoor illumination requirements, by allowing for easy installation of a lamp, particularly, an LED lamp including an LED module and by allowing for installation of an LED lamp in two directions or several directions, if necessary.

Another object of the present invention is to provide one complete lamp using a plurality of components and to prevent noise due to shaking at joints by precluding a gap by strongly fastening Of combining the components.

In order to achieve the objects, the present invention includes a base having open sides and bottom, a housing keeping a printed circuit board with an LED module thereon and connected to a side of the base, and a base cover coupled to the lower portion of the base to fix the connection of the side of the base and the housing.

According to the present invention, it is possible to install a lamp including an LED module even without a specific skill in accordance with desired indoor illumination, so there is no need for unnecessary work for installing a housing for the LED lamp and it is possible to remarkably reduce the cost for installation.

Further, according to the present invention, it is possible to install an LED lamp in accordance with desired indoor illumination. Further, there is no need for installing a base on a ceiling, so an interior effect can be maximized and sufficient indoor illumination can be ensured.

Further, according to the present invention, parts can be firmly fined to the base, it is possible to prevent noise dale to a gap at the joints, as m the case of to single lamp.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a perspective view showing assembled and partially disassembled states of a base and a housing according to a first embodiment of the present invention;

FIG. 2 is an enlarged perspective view a disassembled state of the base and the housing according to the first embodiment of the present invention shown in FIG. 1;

FIG. 3 is a bottom view showing the assembly of the base and the housing according to the first embodiment of the present invention shown in FIG. 1;

FIG. 4 is a view showing a disassembled state of a printed circuit board, an LED module, and an acryl cover, which are coupled to the housing, with the base and the housing combined;

FIG. 5 is a bottom view showing the assembly of the housing and the base according to the first embodiment of the present invention shown in FIGS. 1 to 4;

FIG. 6 is a perspective view showing an example of a base where a housing can be coupled in six directions as a modification of the first embodiment of the present to invention shown in FIGS. 1 to 4;

FIG. 7 is a perspective view in which the base shown in FIG. 6 has been turned over; and

FIG. 8 is a perspective view showing a disassembled state of a base and a housing according to a second embodiment of the present invention.

### DETAILED DESCRIPTION OF THE INVENTION

Hereinafter, exemplary embodiments of the present invention are described in detail with reference to the accompanying drawings.

As shown in the accompanying drawings, the present invention provides a power source lamp base for fixing an LED lamp including an LED module, that is, a power source lamp base that can be installed and fixed in several directions.

To this end, the present invention includes a base 100 having open sides and bottom, a housing 200 keeping a printed circuit board with an LED module thereon and connected to a side of the base 100, and a base cover 300 coupled to the lower portion of the base 100 to fix the connection of the side of the base 100 and the housing 200.

The housing 200 keeping the printed circuit board 100 with an LED module thereon is coupled to the base 100 in two directions, four directions, or six directions, depending on the indoor illumination requirements or usability of the space where it is installed.

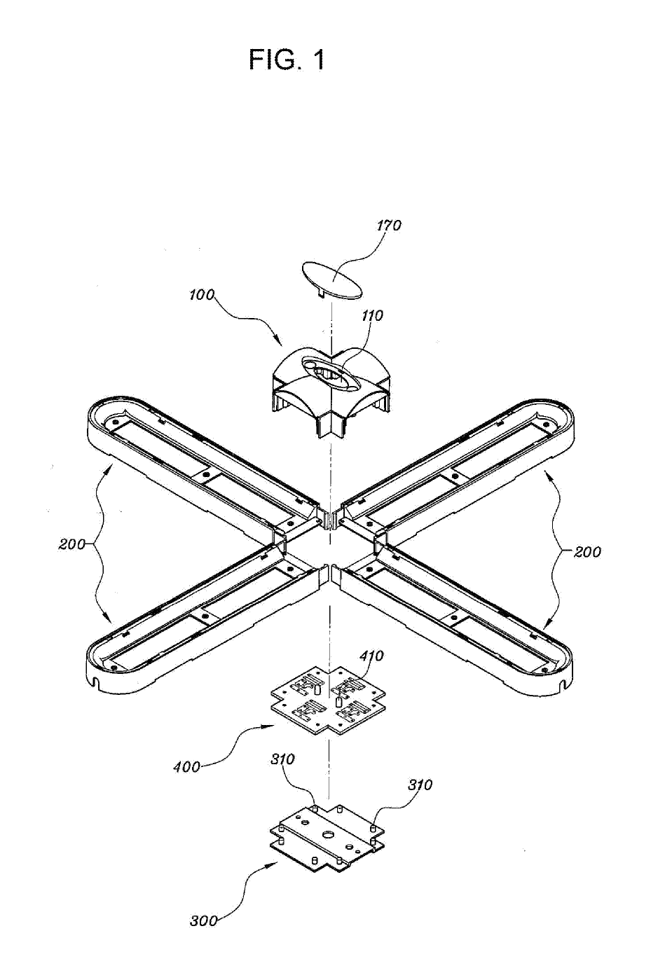

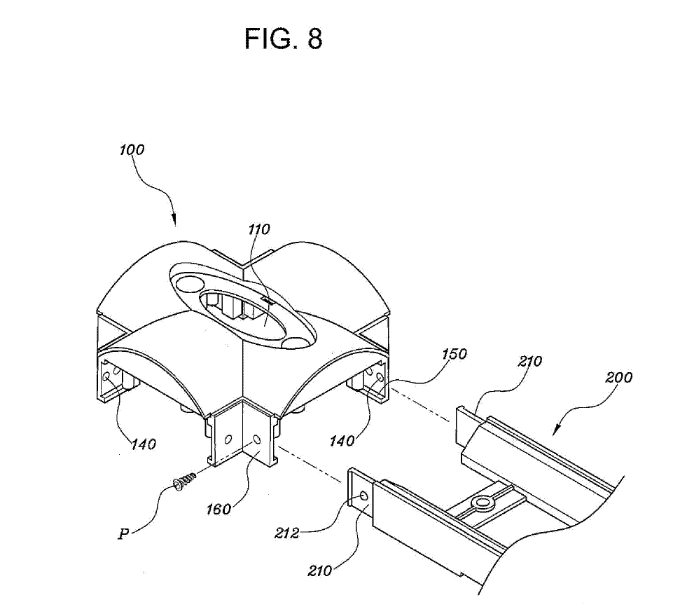

The base 100 may be achieved in first and second embodiments, as shown in FIGS. 1 and 8.

### First Embodiment of Base

First, a first embodiment of the base 100 is described with reference to FIG. 1, in which the housing 200 is coupled in four directions, but it may be coupled in several directions to the base 100 such as two directions or six directions, so the present invention is not limited to the structure shown in the figure.

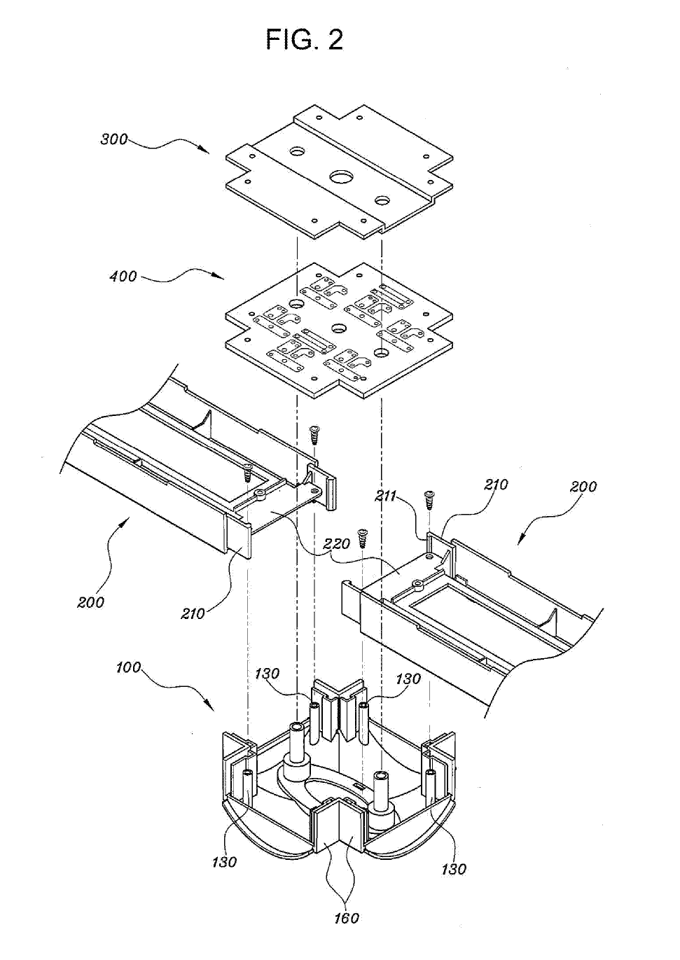

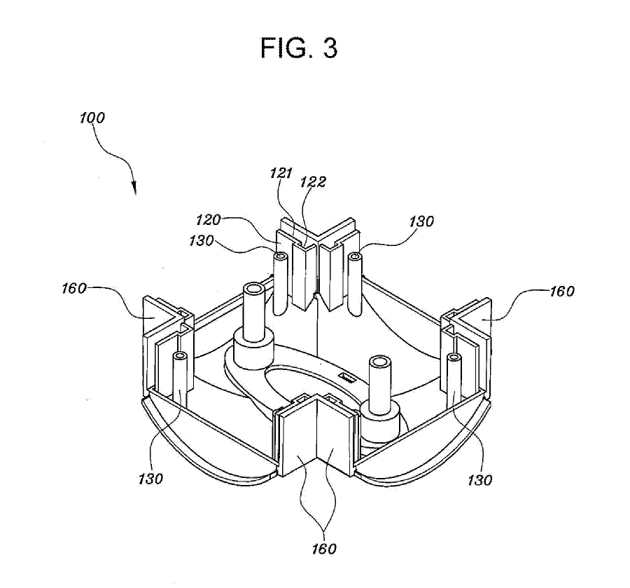

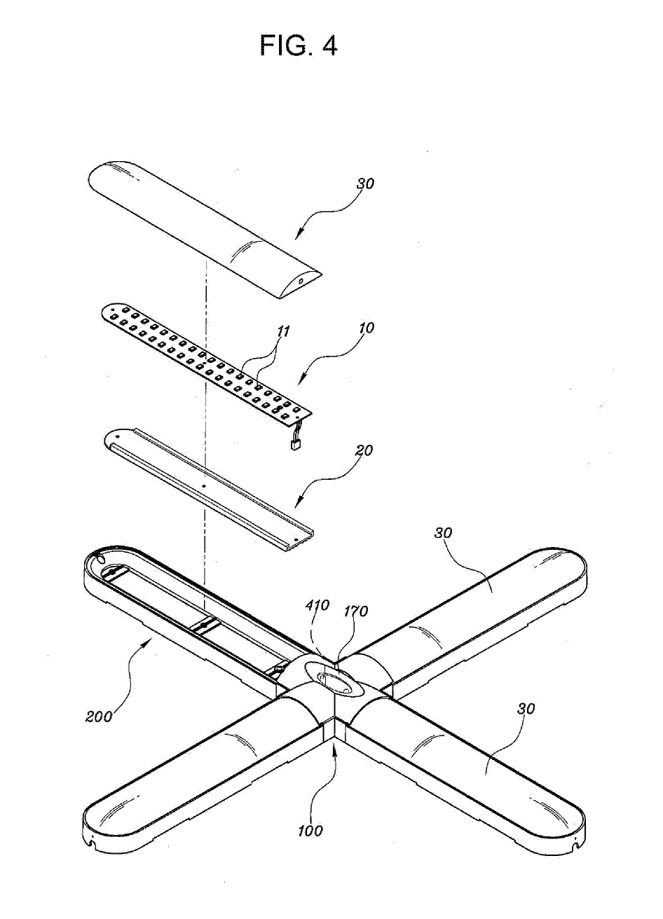

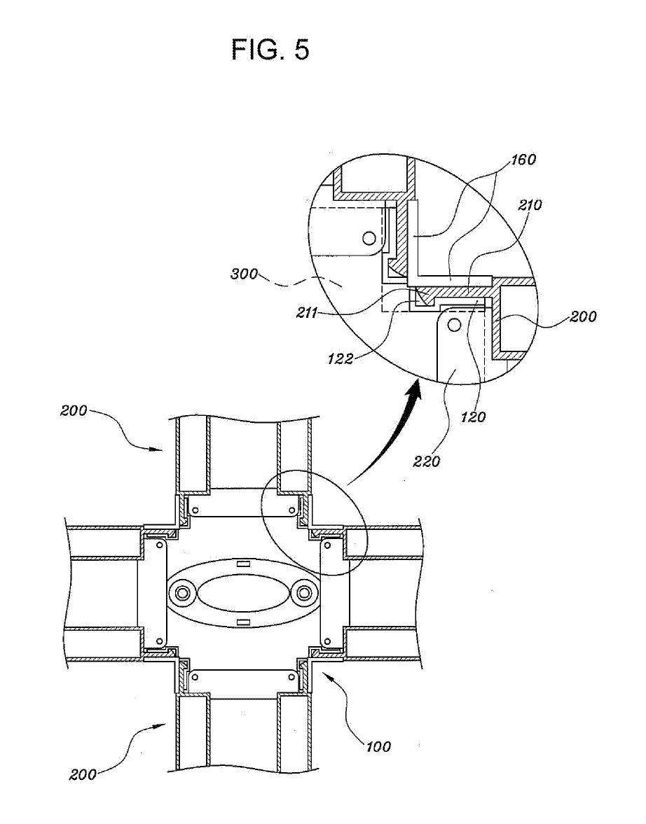

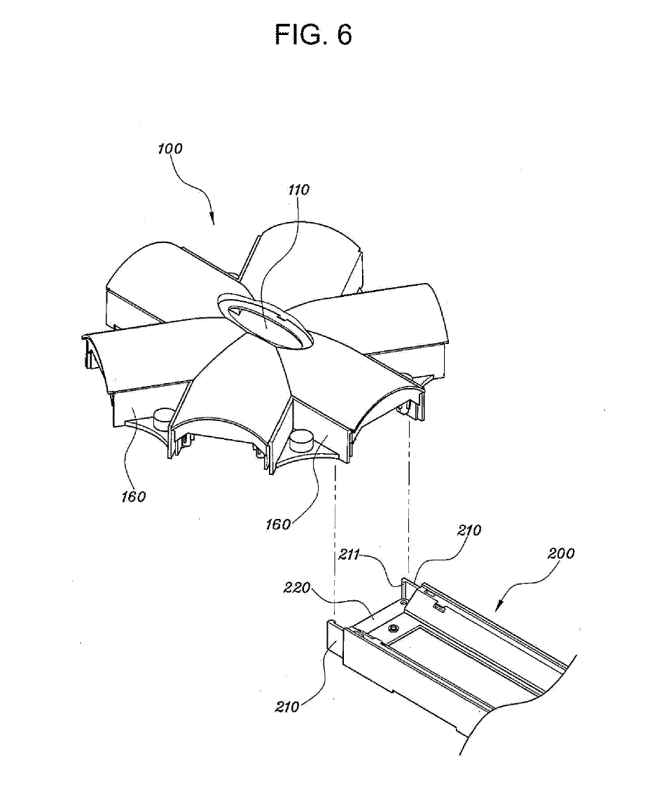

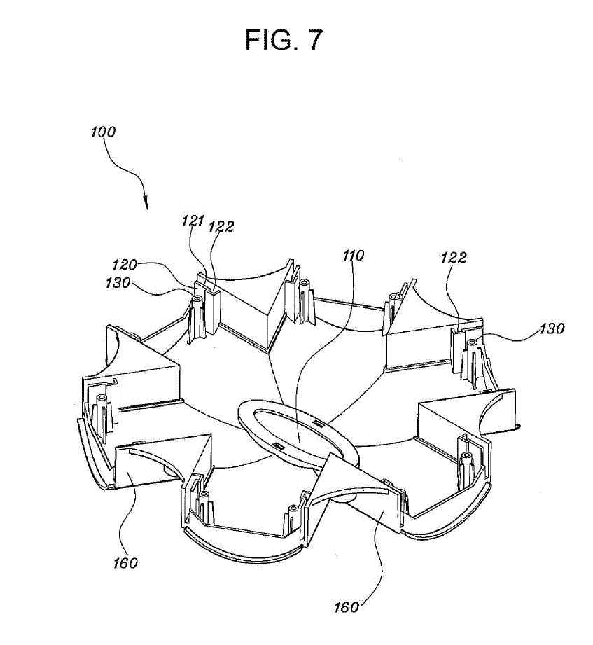

A base according to the first embodiment shown m FIGS. 1 to 7 is indicated by reference numeral ‘100’.

In the base 100, an elliptical hole 110 is formed at the center, insertion grooves 121 open to the front and bottom and second grooves 122 closed at the ends of the insertion grooves 121 and larger than the gap between the insertion grooves 121 are formed inside coupling members 160 forming corners, elastic portions 120 extending to the ends are bent to form the insertion grooves 121 and the second grooves 122, and a plurality of bolt-fastening protrusions 130 is formed to support connection members 220 disposed between extensions 210 of the housing 200 supporting a second printed circuit board 300 for radiating light through an LED 410 to a cover 170 coupled to a base bottom cover 300 and covering the hole 110 of the base 100.

A printed circuit board 10 with an LED module II thereon is fitted in a heat dissipation plate 210 and then seated in the housing 200. This structure of the housing 200 can be achieved front common structures, so well-known components are not described in detail.

However, in order for the housing 200 to perform the desired role and function of the present invention, the extensions 210 extend from an end of the housing 200 and the connection member 220 is disposed between the extensions 210 at the end to support the extensions 210 and the bottom of the second printed circuit board 300.

Further, a projection 211 is formed at ends of the extensions 210 to be fitted in the second grooves 122 of the grooves 121 and 122 formed by the elastic portions 120.

Accordingly, when the extensions 210 at the end of the housing 200, which keeps the printed circuit board 10 having the LED module 11 thereon and is covered with an acryl cover 30 at the top, are slid upward into the spaces formed by the elastic portions 120, the extensions 210 are fitted into the insertion grooves 121 and the second grooves 122 of the base 100.

As described above, the projections 211 at the ends of the extensions 210 are fitted into the second grooves 122, so the housing 200 is not separated even if it is horizontally pulled.

After housings 200 are coupled to the base 100 in four directions through the process described above, the bottom of the base 100 is covered with the base bottom cover 300.

The housings 200 may be coupled to the base 100 in four directions, as described above, or it may be possible to form the base 100 such that the housings 200 can be coupled in six directions.

### Second Embodiment of Base

Unlike the base 100, a second embodiment may be considered.

To this end, in a base 100, an elliptical hole 110 is formed at the center, projection holes 140 are formed on the inner sides of coupling members 160 having guides 150 bending inward at the lower ends, and projections 212 that are inserted into the projection holes 140 are formed on the outer sides of extensions 210 extending at an end of a housing 200.

According to the second embodiment having this configuration, since the housing 200 is not slid upward, as in the first embodiment, it can be coupled in a way of horizontally pushing it at a side of the base 100.

Accordingly, when a printed circuit board 10 with an LED module 11 thereon is horizontally pushed into the side of the base 200 together with a heat dissipation plate 20 along the coupling members 150, with an acryl cover 30 coupled, the extensions 210 are guided by the guide 150 bending inward at the ends of the coupling members 160 of the base 100 and the projections 212 on the outer sides of the extensions 210 are fitted into the projection grooves 140 on the inner sides of the coupling members 160.

In this state, as described above, the housing 200 and the base 100 can be coupled by a base bottom cover 300.

In this state, it may be possible to fix the coupling members 160 with pieces P to firmly fix the coupling members 160 of the base 100 to the extensions 210 of the housing 200 that are inserted inside the coupling members 160.

The holes 110 of the bases 100 are covered with a translucent cover 170 in the first and second embodiments, in which an LED 410 may be connected to the second printed circuit board 400 disposed in the base 100 so that the LED 410 is turned on and light is radiated through the cover 170 when power is supplied.

According to the first and second embodiments of the present invention, the base 100, the second printed circuit board 400, and the base bottom cover 300 can be firmly fastened by bolts, housings 200 can be firmly coupled to sides of the base 100 to achieve the effect like one lamp, and the base 100, the base bottom cover 300, and the housing 200 can be coupled without a gap at the joints, so they can be firmly combined.

Although the present invention was described above through embodiments and figures, the present invention is not limited to the embodiments and may be changed and modified in various ways by those skilled in the art.

What is claimed is:

1. A multi-direction installation practicable LED lighting power source lamp base, comprising: a base haying open sides and an open bottom; a housing keeping a printed circuit board having an LED module thereon, and connected to a side of the base; and a base cover coupled to a lower portion of the base to fix connection of the side of the base and the housing.

2. The power source lamp base of claim 1, wherein an elliptical hole is formed at to a center, insertion grooves open to a front and a bottom and second grooves closed at ends of the insertion grooves and larger than a gap between the insertion grooves are formed inside coupling members forming corners, elastic portions extending to ends lire bent to form the insertion grooves and the second grooves, and a plurality of bolt-fastening protrusions is formed to support connection members disposed between extensions of the housing supporting a second primed circuit board for radiating light from an LED to a cover that is coupled to a base bottom cover and covers the hole of the base.

3. The power source lamp base of claim 1, wherein an elliptical hole is formed at a center, projection holes are formed on inner sides of coupling members having guides bending inward at lower ends, and projections that are inserted into the projection holes are formed on outer sides of extensions extending at an end of a housing.

4. The power source lamp base of claim 1, wherein an elliptical hole is formed at a center, extensions extending at and end of the housing are inserted inside inner sides of coupling members having guides bending inward at lower ends, and the members are fixed by pieces.

5. The power source lamp base of claim 1, wherein extensions extend from an end of the housing and a connection member is disposed between the extensions at an end to support the extensions and a bottom of a second printed circuit board.

6. The power source lamp base of claim 1, wherein an LED is connected to a second printed circuit board disposed in the base to be turned on so that light is radiated through the cover made of a translucent material and covering the hole of the base.

7. The power source lamp base of claim 4, wherein an LED is connected to a second printed circuit board disposed in the base to be turned on so that light is radiated through the cover made of a translucent material and covering the hole of the base.
